(19) United States
(12) Patent Application Publication
(10) Pub. No.: US 2022/0165618 A1
(43) Pub. Date: May 26, 2022

(54) 3D BONDED SEMICONDUCTOR DEVICE AND METHOD OF FORMING THE SAME

(71) Applicant: NANYA TECHNOLOGY CORPORATION, New Taipei City (TW)

(72) Inventor: Yi-Jen LO, New Taipei City (TW)

(21) Appl. No.: 17/103,902

(22) Filed: Nov. 24, 2020

(51) Int. Cl. H01L 21/768; H01L 23/522

(52) U.S. Cl. CPC H01L 21/76846; H01L 23/5226; H01L 21/76898; H01L 21/76813

(57) ABSTRACT

A 3D bonded semiconductor device, which includes a first semiconductor device, a second semiconductor device, an isolation layer, a damascene structure, a barrier layer and a metal layer. The first semiconductor device includes a first substrate and a first conductive pad. The second semiconductor device includes a second substrate and a second conductive pad. The isolation layer covers on a backside of the second semiconductor device. The damascene structure includes a first via hole and a second via hole that respectively land on the first conductive pad and the second conductive pad at the same time, in which a first critical dimension of the first via hole is different from a second critical dimension of the second via hole. The barrier layer forms on the side-walls of the first via hole and the second via hole. The metal layer fills the damascene structure.

### BACKGROUND

### Technical Field

The present disclosure relates to a 3D bonded semiconductor device and method of forming the same. More particularly, the present disclosure relates to a 3D bonded semiconductor device and method of forming the same, which is configured with different depths of via holes.

### Description of Related Art

Three-dimensional (3D) wafer-to-wafer vertical stacking technology is commonly used for vertically connecting multi-layer active integrated circuit (IC) components stacked in a chip to reduce the internal RC delay of the connection. By producing through silicon via (TSV) holes to form 3D interconnects in a single chip or multiple vertical stacking chips, a high impedance signal path from one side of the chip to the other side can be provided.

In a conventional art of forming 3D interconnects in the integrated circuit, trenches and via holes are usually produced in a dual damascene process. In general, the dual damascene process includes via-first process and via-last process. For example, the conventional method of fabricating a dual damascene structure is to etch a dielectric layer to form trenches and via holes. The trenches and via holes are covered with barriers, such as Titanium Nitride (TiN), and then the trench and via holes are filled with copper (Cu).

Furthermore, in order to produce via holes that have different depths in the dual damascene process, additional lithography process is often required in order to tape out different masks and separately etch via holes.

### SUMMARY

One aspect of the present disclosure is to provide a method of forming a 3D bonded semiconductor device, which includes: bonding a first semiconductor device to a second semiconductor device; thinning a backside of the second semiconductor device so as to form an isolation layer; forming a trench on the isolation layer; and forming, at the same time, a first via hole and a second via hole that respectively land on a first conductive pad in the first semiconductor device and a second conductive pad in the second semiconductor device, in which a first critical dimension of the first via hole is different from a second critical dimension of the second via hole.

Some aspects of the present disclosure provide a 3D bonded semiconductor device, which includes a first semiconductor device, a second semiconductor device, an isolation layer, a damascene structure, a barrier layer and a metal layer. The first semiconductor device includes a first substrate and a first conductive pad. The second semiconductor device includes a second substrate and a second conductive pad. The isolation layer covers on a backside of the second semiconductor device. The damascene structure includes a first via hole and a second via hole that respectively land on the first conductive pad and the second conductive pad at the same time, in which a first critical dimension (CD) of the first via hole is different from a second critical dimension (CD) of the second via hole. The barrier layer forms on the side-walls of the first via hole and the second via hole. The metal layer fills the damascene structure.

The 3D bonded semiconductor device and method of forming the same described above provide a method for forming different depths of via holes at the same time, such that extra lithography process can be avoided.

It is to be understood that both the foregoing general description and the following detailed description are by examples, and are intended to provide further explanation of the disclosure as claimed.

### BRIEF DESCRIPTION OF THE DRAWINGS

FIGS. 1-2 are cross-sectional diagrams of semiconductor devices, in accordance with some embodiments of the present disclosure.

FIGS. 3-14 are cross-sectional diagrams illustrating a method of forming the 3D bonded semiconductor device, in accordance with some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

All the terms used in this document generally have their ordinary meanings. The examples of using any terms discussed herein such as those defined in commonly used dictionaries are illustrative only, and should not limit the scope and meaning of the disclosure. Likewise, the present disclosure is not limited to some embodiments given in this document.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

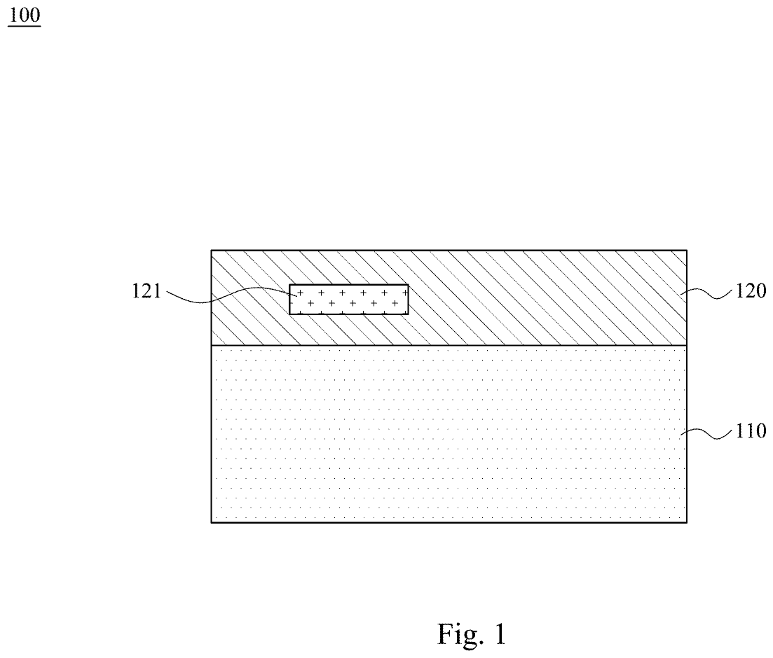

Reference is now made to FIG. 1. FIG. 1 is a cross-sectional diagram of a semiconductor device 100, in accordance with some embodiments of the present disclosure. As shown in FIG. 1, the semiconductor device 100 includes a substrate 110, a bonding layer 120 and a conductive pad 121. The bonding layer 120 is formed on the substrate 110, and the conductive pad 121 is located in the bonding layer 120. In some embodiments, the semiconductor device 100 can be a processor wafer, a memory wafer, or a wafer with any type of IC devices.

In some embodiments, the substrate 110 may include ruthenium, osmium, ruthenium carbide, ruthenium arsenide, a III-V semiconductor compound material, or the like. The substrate 110 can be a bulk substrate, a gallium arsenide (GaAs) substrate, a gallium arsenide-phosphide (GaAsP) substrate, an indium phosphide (InP) substrate, a gallium aluminum arsenic (GaAlAs) substrate, an indium gallium phosphide (InGaP) substrate or a semiconductor-on-insulator (SOI) substrate.

In some embodiments, the bonding layer 120 may be a dielectric layer formed by chemical vapor deposition (CVD), physical vapor deposition (PVD), atomic layer deposition (ALD), the liquid source misted chemical deposition (LSMCD) or by other suitable technology that can form thin layer on the substrate 110. In certain embodiments, the bonding layer 120 may comprise oxide, nitride, nitrogen oxide, advanced low-k materials or other dielectric material. In some embodiments, the conductive pad 121 may be selected from a group of metal such as Copper (Cu), Aluminum (Al), Tungsten (W) or the like.

It should be noted that the bonding layer 120 shown in FIG. 1 is illustrative only. In an actual device, there may be several layers of insulator materials and associated wirings formed therein, and also there may be multiple conductive pads formed in one or more of the bonding layers.

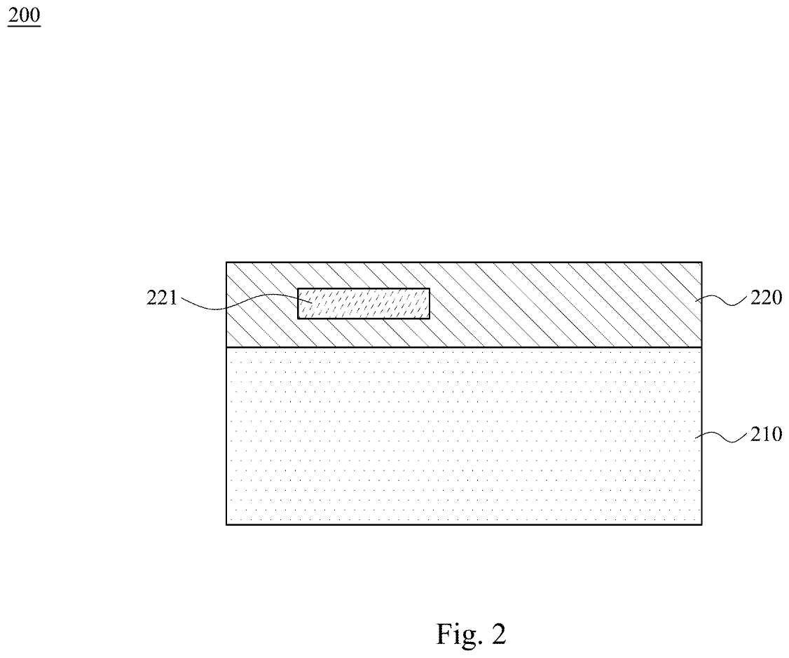

Reference is now made to FIG. 2. FIG. 2 is a cross-sectional diagram of another semiconductor device 200, in accordance with some embodiments of the present disclosure. As shown in FIG. 2, the semiconductor device 200 includes a substrate 210, a bonding layer 220 and a conductive pad 221. The semiconductor device 200 is similar to the semiconductor device 100. For the sake of brevity, those descriptions will not be repeated here.

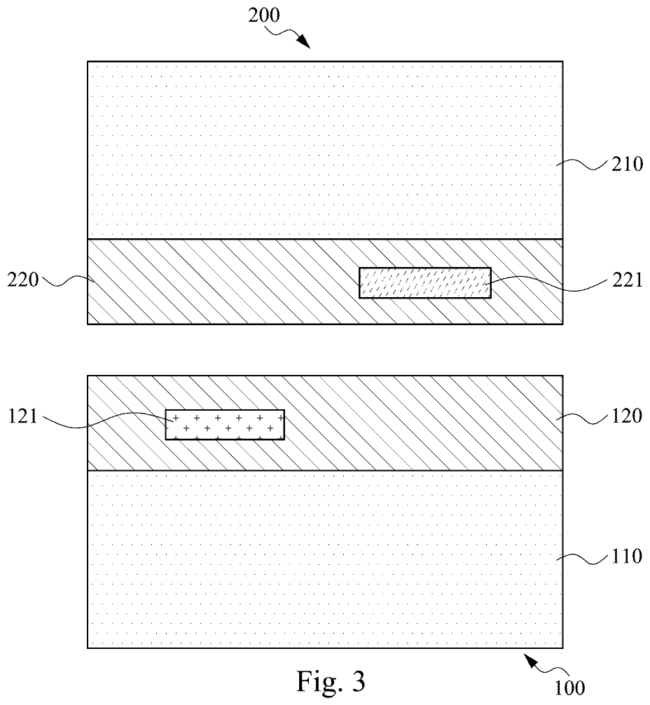

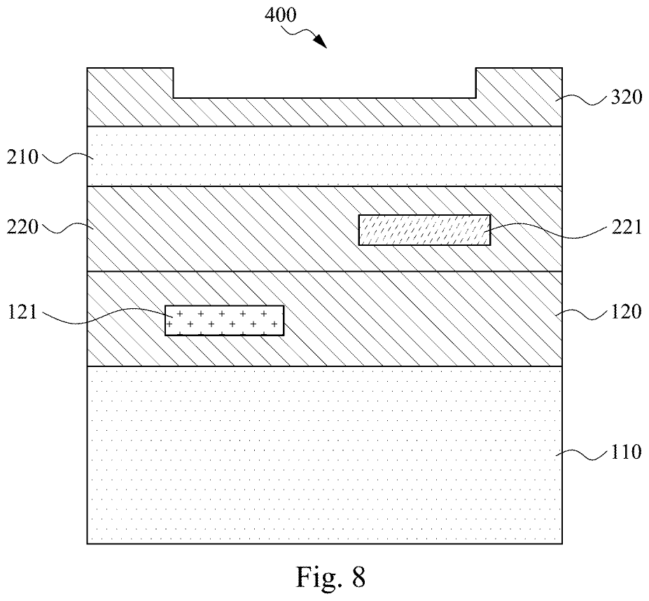

Reference is now made to FIGS. 3-14. FIGS. 3-14 are cross-sectional diagrams illustrating a method 300 of forming a 3D bonded semiconductor device, in accordance with some embodiments of the present disclosure. The method 300 includes bonding the semiconductor device 100 to the semiconductor device 200. As shown in FIG. 3, the bonding layer 220 of the semiconductor device 200 is to be bonded to the bonding layer 120 of the semiconductor device 100. In other words, the semiconductor device 100 and the semiconductor device 200 are face-to-face bonded.

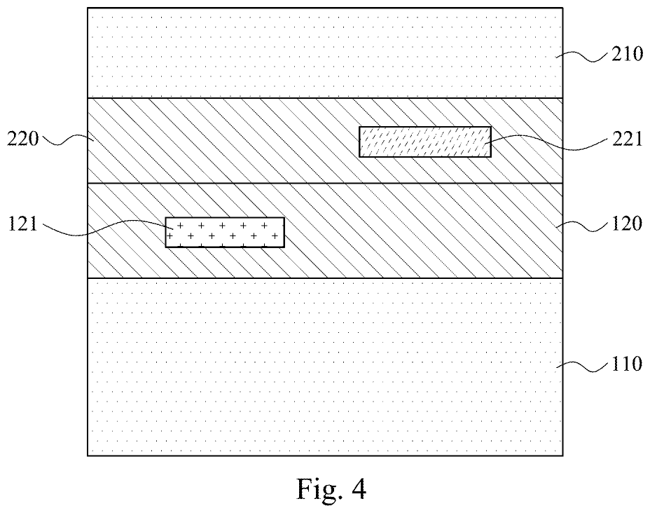

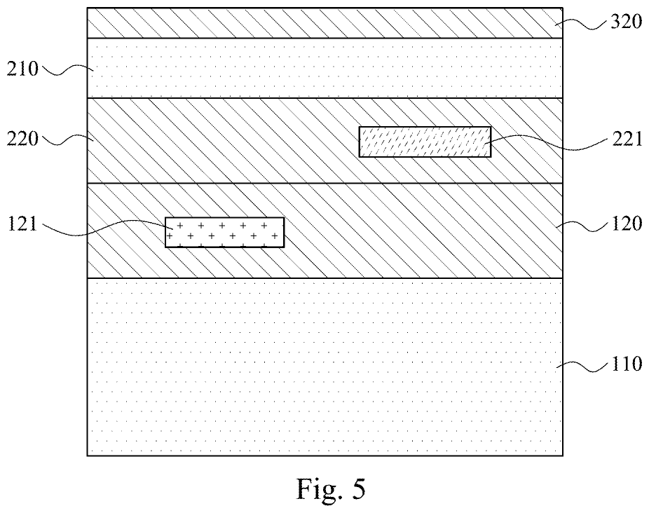

Reference is now made to FIGS. 4-5. A backside of the semiconductor device 200 is thinned so as to form an isolation layer 320 on the substrate 210. More specifically, a predetermined portion of the substrate 210 of the semiconductor device 200 is removed through etching or chemical polishing (CMP) process in order to form the isolation layer 320. In some embodiments, the isolation layer 320 may comprise silicon oxide (SiO), silicon nitride (SiN), silicon carbide (SiC) or the like materials.

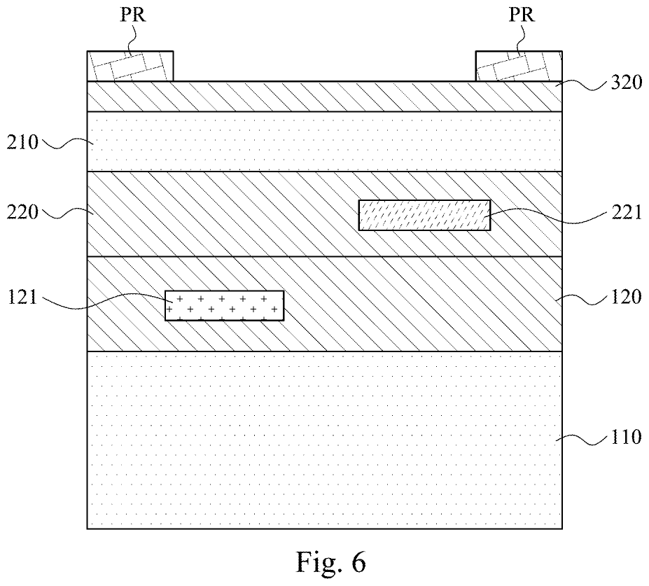

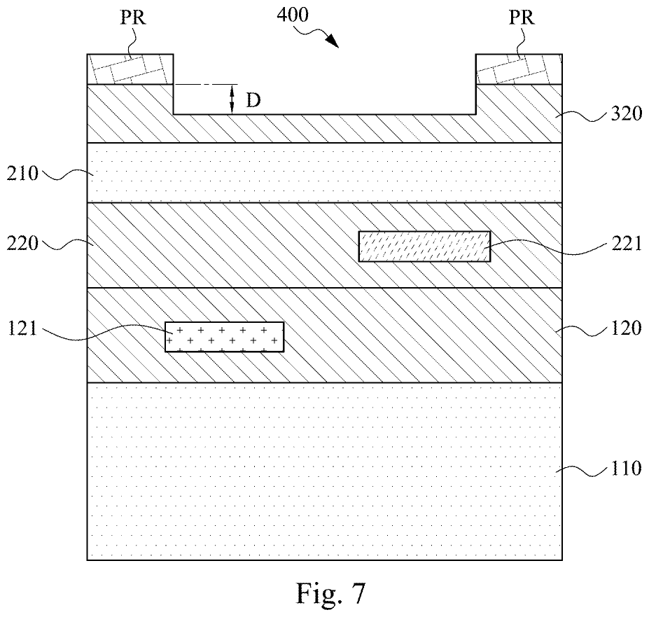

Reference is now made to FIGS. 6-8. FIGS. 6-8 illustrate performing a lithography process to form a trench of a damascene structure on the isolation layer 320. This may include, for example, forming a photoresist layer PR on the isolation layer 320 to define a pattern of the trench. Then, an etching process is performed according to the pattern of the trench, and the remaining photoresist layer PR on the isolation layer 320 is removed. For instance, as shown in FIG. 7, a trench 400 is formed with a desired depth D by etching the isolation layer 320. The desired depth D (i.e., thickness of removed portion of the isolation layer 320) may be predetermined by multiple etching parameters associated with an etching-rate and an etching period of the isolation layer 320. Those skilled in the art can select required etching parameters accordingly to form the trench 400.

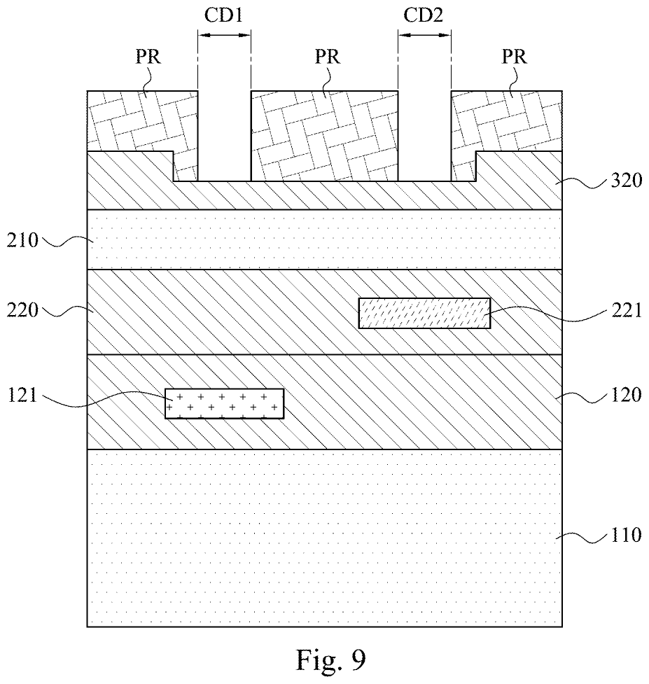

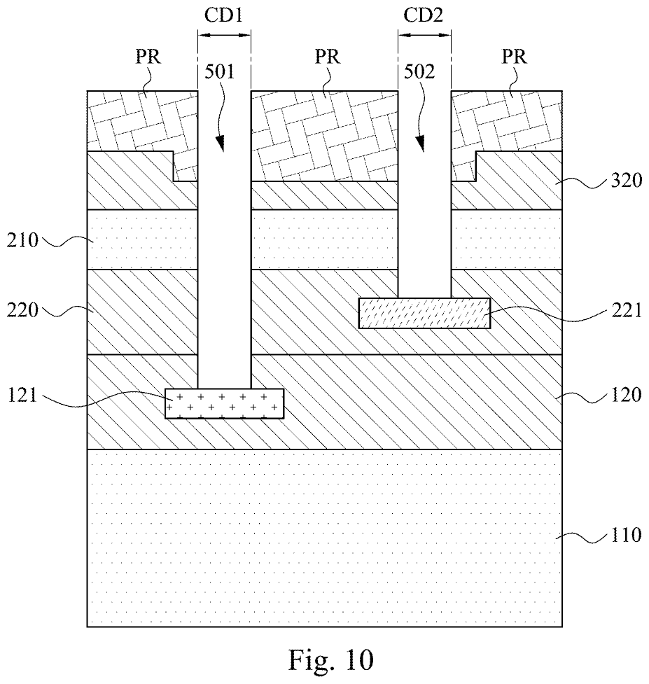

Reference is now made to FIGS. 9-10. A first via hole 501 and a second via hole 502 are defined by via patterning and etching. More specifically, the first via hole 501 with a first critical dimension CD1 and the second via hole 502 with a second dimension CD2 are formed at the same time (i.e., the first via hole 501 and the second via hole 502 are formed by one time exposure in the same lithography process). In addition, the first via hole 501 is formed through the isolation layer 320, the substrate 210, the bonding layer 220, and the bonding layer 120 to land on the conductive pad 121, and the second via hole 502 is formed through the isolation layer 320, the substrate 210 and the bonding layer 220 to land on the conductive pad 221.

In some embodiments, forming the first via hole 501 and the second via hole 502 at the same time also includes, for example, forming another photoresist layer PR so as to define a first pattern of the first via hole 501 and a second pattern of the second via hole 502, in which the first critical dimension CD1 of the first pattern is at least 10% larger than the second critical dimension CD2 of the second pattern. Then, another etching process is performed according to the first pattern and the second pattern.

In this way, by defining different critical dimensions (e.g., CD1 and CD2) for the first pattern and the second pattern, the first via hole 501 and the second via hole 502 both formed in the same exposure with same etching parameters can be controlled to land on different layers (e.g., conductive pads 121, 221) at the same time.

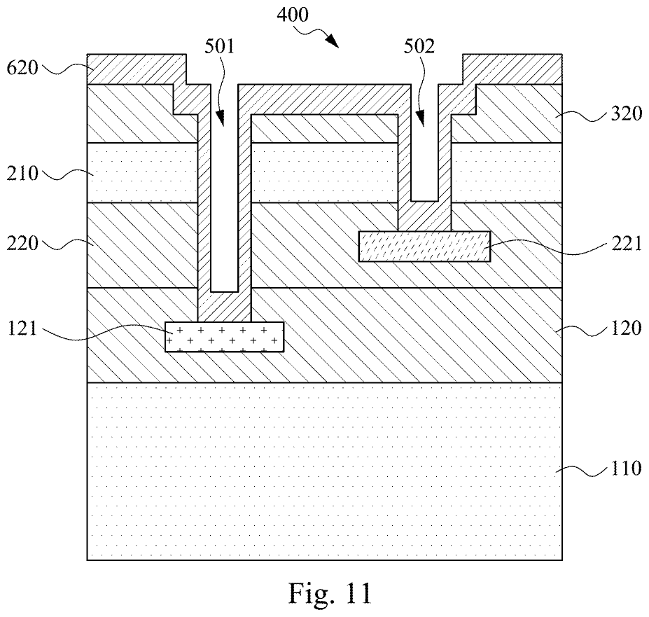

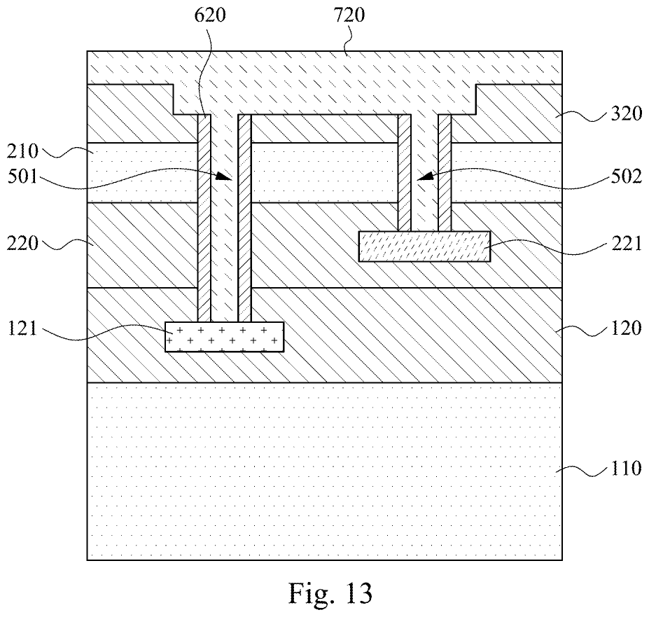

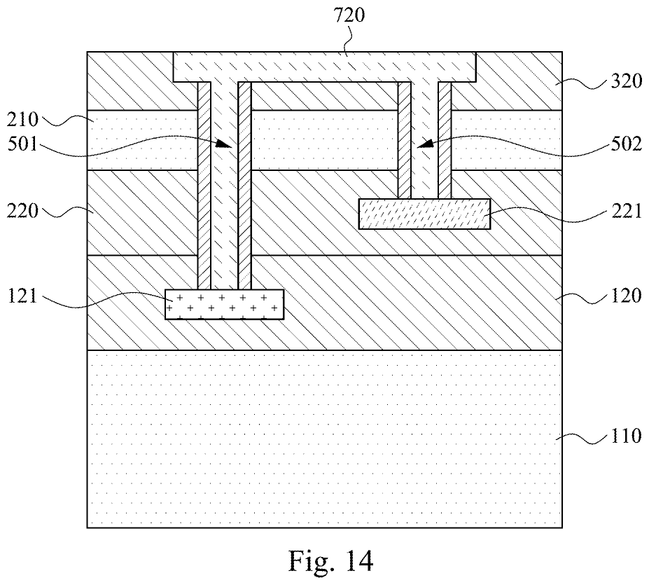

Reference is now made to FIG. 11. A barrier layer 620 is formed on the top surface of the 3D bonded semiconductor device, including portions on the isolation layer 320 and a bottom and side-walls of the first via hole 501 and the second via hole 502. The barrier layer 620 is configured to prevent any electric conducting material in via holes (e.g., Cu in the via holes 501, 502 as shown in FIGS. 13-14) from being diffused into other regions (e.g., the bonding layer 120, 220) of the 3D bonded semiconductor device. In some embodiments, the barrier layer 620 may be formed by performing chemical vapor deposition (CVD), physical vapor deposition (PVD) or atomic layer deposition (ALD), and the barrier layer 620 may be silica, silicon nitride or aforesaid combination etc.

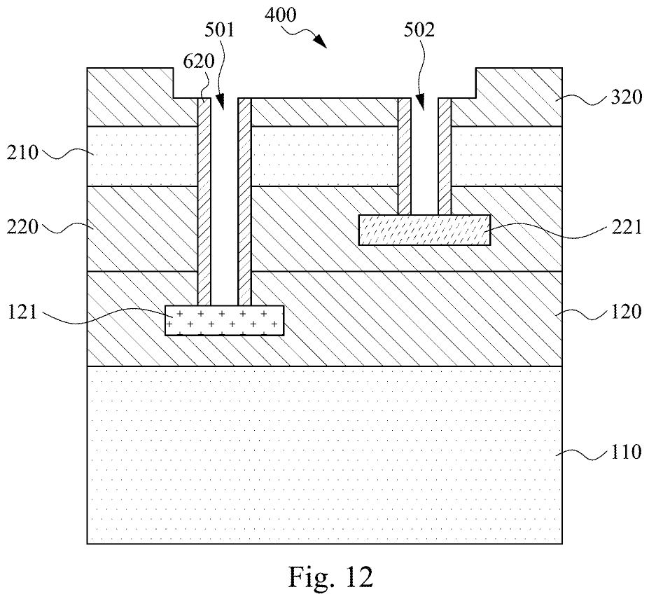

Reference is now made to FIGS. 12-13. The method 300 further includes punching through the barrier layer 620 on the bottom of the first via hole 501 and the second via hole 502 to expose the conductive pad 121 and the conductive pad 221, respectively. Then, a metal filling process is carried out to obtain good electrical conductivity. More specifically, a metal layer 720 is covered on the isolation layer 320 and filled in the damascene structure including the trench 400, the first via hole 501 and the second via hole 502. Therefore, the trench 400, the first via hole 501 and the second via hole 502 are electrically connected to each other through the metal layer 720. In some embodiments, the metal layer 720 is formed by performing copper electroplating on the 3D bonded semiconductor device.

Reference is now made to FIG. 14. The method 300 of forming the 3D bonded semiconductor device is completed by removing excessive portions of the metal layer 620 on the isolation layer 320 as shown in FIG. 13, either through etching or chemical polishing (CMP) process or the like.

While the disclosure has been described by way of example(s) and in terms of the preferred embodiment(s), it is to be understood that the disclosure is not limited thereto. Those skilled in the art may make various changes, substitutions, and alterations herein without departing from the spirit and scope of the present disclosure. In view of the foregoing, it is intended that the present invention cover modifications and variations of this invention provided they fall within the scope of the following claims.

1. A method of forming a 3D bonded semiconductor device, comprising:
bonding a first semiconductor device to a second semiconductor device;
thinning a backside of the second semiconductor device so as to form an isolation layer;
forming a trench on the isolation layer; and
forming, at the same time, a first via hole and a second via hole that respectively land on a first conductive pad in the first semiconductor device and a second conductive pad in the second semiconductor device, wherein a first critical dimension (CD1) of the first via hole is different from a second critical dimension (CD2) of the second via hole, wherein the first critical dimension and the second critical dimension are a width of the first via hole and a width of the second via hole respectively.

2. The method of claim 1, wherein forming the trench on the isolation layer comprises:
forming a photoresist layer on the isolation layer to define a pattern of the trench;
performing an etching process according to the pattern of the trench; and
removing the remaining photoresist layer.

3. The method of claim 1, wherein forming the first via hole and the second via hole at the same time comprises:
forming a photoresist layer so as to define a first pattern of the first via hole and a second pattern of the second via hole, wherein a first critical dimension of the first pattern is at least 10% larger than a second critical dimension of the second pattern; and
performing a etching process according to the first pattern and the second pattern.

4. The method of claim 1, wherein the first semiconductor device and the second semiconductor device are face-to-face bonded.

5. The method of claim 1, wherein the first conductive pad and the second conductive pad are Copper (Cu), Aluminum (Al) or Tungsten (W).

6. The method of claim 1, further comprising:
forming a barrier layer cover on the isolation layer, a bottom and side-walls of the first via hole and the second via hole;
punching through the barrier layer on the bottom of the first via hole and the second via hole to expose the first conductive pad and the second conductive pad, respectively; and
removing portions of the metal layer on the isolation layer.

7. A 3D bonded semiconductor device comprising:
a first semiconductor device, comprising a first substrate and a first conductive pad;
a second semiconductor device, comprising a second substrate and a second conductive pad;
an isolation layer cover on a backside of the second semiconductor device; and
a damascene structure, comprising a first via hole and a second via hole that respectively land on the first conductive pad and the second conductive pad at the same time, wherein a first critical dimension of the first via hole is different from a second critical dimension of the second via hole, wherein the first critical dimension and the second critical dimension are a width of the first via hole and a width of the second via hole respectively;
a barrier layer forming on the side-walls of the first via hole and the second via hole; and
a metal layer filling the damascene structure.

8. The 3D bonded semiconductor device of claim 7, wherein the damascene structure further comprises:
a trench, electrically connected to the first via hole and the second via hole through the metal layer.

9. The 3D bonded semiconductor device of claim 7, further comprising:
a bonding layer configured to bond the first semiconductor device to the second semiconductor device.

10. The 3D bonded semiconductor device of claim 7, wherein the first critical dimension is at least 10% larger than the second critical dimension.

11. The 3D bonded semiconductor device of claim 7, wherein the first conductive pad and the second conductive pad are Copper (Cu), Aluminum (Al) or Tungsten (W).
